(19) United States
(12) Patent Application Publication
(10) Pub. No.: US 2025/0076404 A1
(43) Pub. Date: Mar. 6, 2025

(54) SYSTEM FOR REDUCING BATTERY CELL FAILURE PROPAGATION RISK OF A RECHARGEABLE BATTERY

(71) Applicant: EaglePicher Technologies, LLC, Joplin, MO (US)

(72) Inventors: Stuart Guy SANTEE, Pawcatuck, CT (US); Frank Puglia, Richmond, RI (US); Kristopher John Frutschy, West Greenwich, RI (US); Kenneth Martin Cavanagh, Coventry, RI (US)

(21) Appl. No.: 18/820,051

(22) Filed: Aug. 29, 2024

Related U.S. Application Data
(60) Provisional application No. 63/535,717, filed on Aug. 31, 2023.

(51) Int. Cl. G01R 31/396; G01K 3/00; G01R 31/3835; H01M 10/42; H01M 50/213; H02J 7/00

(52) U.S. Cl. CPC G01R 31/396; G01K 3/005; G01R 31/3835; H01M 10/4257; H01M 50/213; H02J 7/0013; H02J 7/00712; H01M 2010/4271

(57) ABSTRACT

Aspects of the present disclosure include systems, apparatuses, or methods for a system for reducing battery cell failure propagation risk includes a rechargeable battery including a plurality of rechargeable cells connected in series, parallel, or a combination of series and parallel and a BMS coupled with the battery. The BMS includes a processor and a memory including computer-executable instructions to receive information indicative of a status of each of the rechargeable cells; determine that a particular rechargeable cell is likely in a failure condition; identify a group of rechargeable cells that is in within one hop of the rechargeable cell that is likely in the failure condition; couple the group of rechargeable cells to a discharging system without coupling the rechargeable cell in the failure condition to the discharging system; and discharge the group of rechargeable cells to a target SOC.

### CROSS-REFERENCE TO RELATED APPLICATION

This application claims the benefit of U.S. Provisional Patent Application No. 63/535,717, filed Aug. 31, 2023, and hereby incorporates by reference herein the contents of this application.

### TECHNICAL FIELD

Aspects of the present disclosure relate to reducing the risk of a failed or failing battery cell in a battery pack from causing failure of nearby cells in the battery pack.

### BACKGROUND

Electrochemical cells are used as power sources in various devices and applications. Such cells are utilized as battery packs for supplying power to, e.g., electronics, electric vehicles, land vehicles, aircraft and/or marine vessels. These cells are commonly used in packs in which multiple cells are packed in close proximity, in order to achieve high energy density and small size. Due to the closeness of the cells to one another, if a cell emits hot gases and materials (e.g., due to internal short, thermal runaway or other event that causes the cell to fail), this release can cause damage to and/or failure of cells in close contact with the failing cell. It would be desirable to provide improved designs for cells or battery packs that provide protection from damage and prevent or assist in reducing thermal runaway of a cell in a battery pack from damaging other cells and potentially causing a cascading failure of cells in close proximity to the failing cell, which can lead to destruction of the battery pack and/or damage of equipment including the battery pack.

### SUMMARY

This summary is provided to introduce a selection of concepts in a simplified form that are further described below in the DETAILED DESCRIPTION. This summary is not intended to identify key features of the claimed subject matter, nor is it intended to be used as an aid in determining the scope of the claimed subject matter.

In some aspects, a system for reducing battery cell failure propagation risk of a rechargeable battery includes a rechargeable battery and a battery management system (BMS). The rechargeable battery includes a plurality of rechargeable cells connected in series, parallel, or a combination of series and parallel. The BMS is coupled with the battery. The BMS may include a processor and a memory. The processor is configured to execute computer-executable instructions stored on the memory. The memory includes computer-executable instructions to receive, from one or more sensors, information indicative of a status of each of the rechargeable cells of the plurality of rechargeable cells; determine, based on the information indicative of the status of the plurality of rechargeable cells, that a particular rechargeable cell is likely in a failure condition, wherein the failure condition incudes at least one of undergoing thermal runaway and likely to enter thermal runway; identify a group of rechargeable cells of the plurality rechargeable cells that is in within one hop of the rechargeable cell that is likely in the failure condition; couple the group of rechargeable cells to a discharging system without coupling the rechargeable cell in the failure condition to the discharging system; and discharge the group of rechargeable cells to a lower, target State of Charge (SOC), where cell failure may be less likely, delayed and less energetic.

In some aspects, a system for reducing battery cell failure propagation risk of a rechargeable battery includes a rechargeable battery and a battery management system (BMS). The rechargeable battery includes a plurality of rechargeable cells connected in series, parallel, or a combination of series and parallel. The BMS is coupled with the battery. The BMS includes a processor and a memory. The processor is configured to execute computer-executable instructions stored on the memory. The memory including computer-executable instructions to: receive, from one or more sensors, information indicative of a status of each of the rechargeable cells of the plurality of rechargeable cells; determine, based on the information indicative of the status of the plurality of rechargeable cells, that a particular rechargeable cell is likely in a failure condition, wherein the failure condition includes cells likely to undergo thermal runaway; identify a group of rechargeable cells of the plurality rechargeable cells that is one hop away from the rechargeable cell that is likely in the failure condition; couple the group of rechargeable cells and the cell in the failure condition to a discharging system; and discharge the group of rechargeable cells and the cell in the failure condition to a target State of Charge (SOC), wherein the cell in the failure condition is not discharged before the group of rechargeable cells is discharged.

In some aspects, a system for reducing battery cell failure propagation risk of a rechargeable battery includes a rechargeable battery and a battery management system (BMS). The rechargeable battery includes a plurality of rechargeable cells connected in series, parallel, or a combination of series and parallel. The BMS is coupled with the battery. The BMS includes a processor and a memory. The processor is configured to execute computer-executable instructions stored on the memory. The memory includes computer-executable instructions to: receive, from one or more sensors, information indicative of a status of each of the rechargeable cells of the plurality of rechargeable cells; determine, based on the information indicative of the status of the plurality of rechargeable cells, that a particular rechargeable cell is likely in a failure condition; identify a first group of rechargeable cells of the plurality rechargeable cells that is one hop away from the rechargeable cell that is likely in the failure condition; identify a second group of rechargeable cells of the plurality rechargeable cells that two hops away from the rechargeable cell that is likely in the failure condition; in response to determining that the first group of cells can likely be discharged before the cells in the first group of rechargeable cells enter the failure condition, couple the first group of rechargeable cells to a discharging system and discharge the first group of rechargeable cells to a target State of Charge (SOC); or in response to determining that the first group of rechargeable cells cannot likely be discharged before the cells in the first group of rechargeable cells enter the failure condition, couple the second group of rechargeable cells to the discharging system and discharge the second group of rechargeable cells to the target SOC.

### BRIEF DESCRIPTION OF THE DRAWINGS

The features believed to be characteristic of aspects of the disclosure are set forth in the appended claims. In the description that follows, like parts are marked throughout the specification and drawings with the same numerals, respectively. The drawing figures are not necessarily drawn to scale and certain figures may be shown in exaggerated or generalized form in the interest of clarity and conciseness. The disclosure itself, however, as well as a preferred mode of use, further objects, and advantages thereof, will be best understood by reference to the following detailed description of illustrative aspects of the disclosure when read in conjunction with the accompanying drawings, wherein:

FIG. 1 illustrates an example battery system with a failing battery cell in a first configuration in accordance with aspects of the disclosure.

FIG. 2 illustrates the battery system of FIG. 1 with a failing battery cell in a second configuration in accordance with aspects of the disclosure.

FIG. 3 illustrates the battery system of FIG. 1 with a failing battery cell in a third configuration aspect in accordance with aspects of the disclosure.

FIG. 4A illustrates an example battery management system (BMS) for use with the battery system of FIG. 1 in accordance with aspects of the disclosure.

FIG. 4B illustrates an example discharging system for use with the battery system of FIG. 1 in accordance with aspects of the disclosure.

FIG. 4C illustrates an schematic representation of battery cells coupled to the example discharging system of FIG. 4B.

FIG. 5 illustrates a method for reducing the risk of propagation of thermal runaway in a rechargeable battery, such as the battery system of FIG. 1 in accordance with aspects of the disclosure.

FIG. 6 illustrates another method for reducing the risk of propagation of thermal runaway in a rechargeable battery, such as the battery system of FIG. 1 in accordance with aspects of the disclosure.

FIG. 7 illustrates a temperature map (e.g., a heat map) of the battery system of FIG. 1 in which a cell of the battery is undergoing a thermal runaway event and the cells in close proximity to the cell undergoing the thermal runaway event have been discharged in accordance with aspects of the disclosure.

FIG. 8 illustrates an example system diagram of various hardware components and other features for use with the battery system of FIG. 1 in accordance with aspects of the present disclosure.

FIG. 9 illustrates a representative block diagram of various example system components for use with the battery system of FIG. 1 in accordance with aspects of the present disclosure.

### DETAILED DESCRIPTION

The following includes definitions of selected terms employed herein. The definitions include various examples and/or forms of components that fall within the scope of a term and that may be used for implementation. The examples are not intended to be limiting.

Aspects of the present disclosure are generally related to systems, apparatuses, and methods for reducing the risk of propagation of thermal runaway events across multiple cells in a battery. In aspects of the disclosure, cell(s) in thermal runaway and/or that are likely to undergo thermal runaway (e.g., cell(s) in a failure condition) are identified by a controller. Next, cells in close contact with the cell(s) in the failure condition are identified. These cells are then discharged to a target state of charge (SOC), which reduces the risk that these cells will undergo thermal runway. In the event that these cells do undergo thermal runaway, these cells will release less energy and will release energy at a slower rate than cells that have not been discharged. Therefore, discharging the cells in close contact with the failing cell provides a protective “fence” around the failing cell that can prevent or assist in reducing the failure condition from spreading to cells that are not in close proximity to the failing cell. This can assist in protecting the remaining cells in the battery and/or prevent or assist in reducing damage of device(s) coupled with the battery.

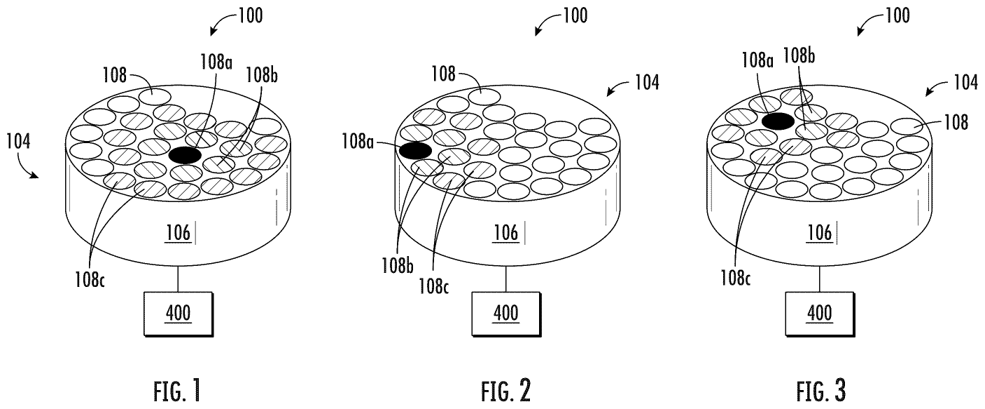

FIGS. 1-3 illustrate a battery system 100 according to aspects of the present disclosure. The system 100 includes a rechargeable battery 104 including a housing 106 including a plurality of rechargeable cells 108a-108n, where n is a whole number greater than 1 (collectively referred to as rechargeable cells 108). The cells 108 may be electrically connected with each other in series, parallel, or a combination of series and parallel. In some aspects, the cells 108 may be lithium-ion cells. In other aspects, the cells 108 may have other chemistries, such as, for example both rechargeable and primary battery systems including lithium metal, silver zinc, nickel cadmium, lead acid, nickel zinc, sodium ion, and so forth.

The battery system 100 further includes a battery management system (BMS) 400 that is electrically coupled with each of the cells 108. The BMS 400 is configured to determine a health status of the cells 108. For example, the BMS 400 is configured to determine whether each of the cells is operating under acceptable operating conditions or is in a failure condition. In response to determining that any of the cells 108 is in a failure condition, the BMS 400 is configured to discharge the cells 108b one hop away from the failing cell 108a and/or discharge the cells 108c two hops away from the failing cell 108a, as described in greater detail below.

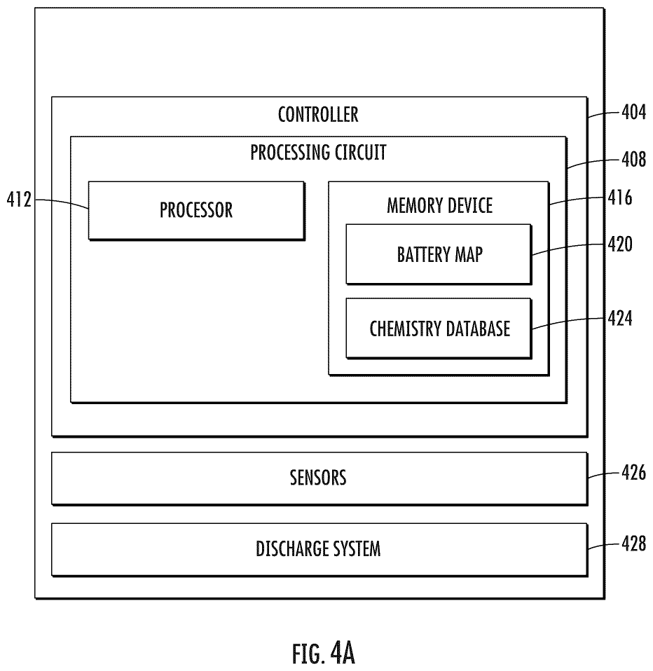

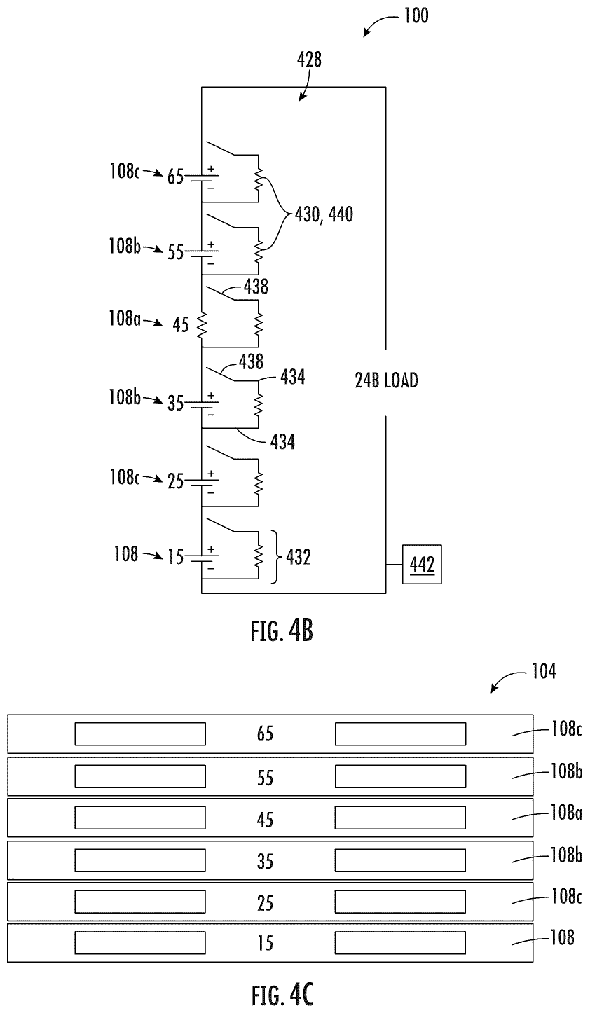

As shown in FIG. 4A, the BMS 400 includes a controller 404 including a processing circuit 408 including a processor 412 and a memory device 416. The processor 412 is configured to execute instructions stored in the memory device 416. The memory device 416 may include a battery map 420 that includes information indicative of each particular rechargeable cell 108 relative to the other cells 108. For example, for each particular cell 108, the battery map 420 may include information indicative of the identities and/or locations of each of the other cells 108 that is in close contact with the particular rechargeable cell 108. As used herein, the phrase “close contact” refers to cells in direct physical contact, near each other (e.g., adjacent each other), in electrical contact with each other, and/or in a path of gasses released by the failing cell 108a. For example, FIGS. 1-3 show various configurations of battery systems 100 that include a cell 108a in a failure condition. The battery map 240 includes information indicative of the identities of the cells 108b that are in close contact with the cell 108a. The cells 108b are interchangeably referred to herein as being one hop away from the failing cell 108. As used herein, the phrase “one hop” means these cells are adjacent to or one cell away from a particular cell, e.g., the failing cell 108a. Further, in some aspects, the battery map 420 may further include information indicative of the identities and/or locations of each of the other cells 108c that are in close contact to the particular cells 108b that are in close contact with the particular rechargeable cell 108a that is in the failure condition. The cells 108c are interchangeably referred to herein as being two hops away from the failing cell 108a. In other words, cells 108c are two cells away from the failing cell 108a or one hop away from the cells 108b which are adjacent to the failing cell 108a. In some aspects, the memory device 416 may include a lookup table that includes the information indicative of each particular rechargeable cell 108 relative to the other cells 108. For example, for each particular cell 108, the lookup table may include information indicative of the identities and/or locations of each of cells 108b are one hop away from the particular rechargeable cell 108. The lookup table may further include information indicative of the identities and/or locations of each of the other cells 108c that are two hops away from a particular rechargeable cell.

In aspects in which the battery 104 includes one or more strings of cells 108 connected in parallel, a short in a particular cell 108 typically causes discharge of all cells 108 in the string of parallel cells 108 through the shorted cell 108. In such instances, the string of cells 108 including the shorted cell 108 are all designated as failing cells 108a. Therefore, in such aspects, cells 108b correspond to strings of cells 108b connected in parallel that are adjacent to the string of failing cells 108a. In such aspects, cells 108c correspond to strings of cells 108c connected in parallel that are adjacent to the strings of cells 108b.

In some aspects, the memory device 416 may include a chemistry database 424. The chemistry database 424 may include a failure temperature for each chemistry of battery cell 108 used in the battery pack 104. The chemistry database 428 may also include, for each type of battery cell 108 used in the battery pack 104, a target SOC threshold at which a particular cell 108 should be designated as a failed cell 108a. The chemistry database 428 may also include, for each type of battery cell 108 used in the battery pack 104, a target SOC threshold at which a discharging should stop for each particular cell 108b, 108c.

The BMS 400 further includes sensors 426 coupled with each of the cells 108. In some aspects, the sensors 426 may include temperature sensors and/or voltage sensors.

The BMS 400 further includes a discharge system 428 (FIG. 4B) couplable with the cells 108 and configured to discharge one or more particular battery cells 108 relatively quickly. A schematic representation of the cells 108a-108c coupled to the discharge system 248 is shown in FIG. 4C. The discharge system 428 includes a path of discharge 432 that includes a resistive discharge balancing circuit 436, one or more dedicated discharge resistor(s) 440, and/or any other suitable energy-absorbing component or apparatus that is coupled with each of the cells 108 to discharge that particular cell 108. The path of discharge 432 includes wires 434 and switches 438 that can be used to selectively connect each of the cells 108a to the path of discharge 432. In some aspects, the resistors 440 in the resistive discharge balancing circuit 436 may be used to discharge the particular cells 108b, 108c. In some aspects, the discharge resistor(s) 440 may be dedicated discharge resistors that are separate from the resistive discharge balancing circuit 436. In some aspects, the discharge resistor(s) 440 may be external to the battery 104. In some aspects, the discharge resistor(s) 440 may be coupled with a cooling system or a heat sink 442 configured to cool the discharge resistor(s) 440 and/or the heat from the discharge pathway 432 using convection, conduction, and/or radiation. The heat sink 442 is a schematic representation of a heat sink, and the heat sink 442 may be coupled elsewhere in the system 100, multiple heat sinks 442 may be used, and so forth. In some aspects, the cooling system may include one or more fans configured to remove heat from the discharge resistor(s) 440. In another aspect, aspects, the discharge resistor(s) 440 may be immersed in liquid such as water and/or include a resistor that is cooled with a liquid such as water. In some aspects, the discharging of the identified cells can be achieved by utilizing existing BMS designs that have cell balancing capabilities through resistive discharge, such as the resistive discharge balancing circuit 436, which could be applied as the default discharge path. In some aspects, the discharging of the identified cells can be achieved by utilizing alternative discharge paths that could be designed where the existing BMS uses an alternate method of balancing. In some aspects, the discharging of the identified cells can be achieved by utilizing the higher heat/load capacity set of resistors 440 dedicated for the discharge path 432.

In some aspects, the rate of discharge of the cells 108b, 108c may be determined based on the chemistry of the cells 108b, 108c, the configuration of the discharge circuit 436 and/or discharge resistors 440, and/or the temperature of the battery 104 and/or the cells 108a, 108b, and/or 108c. For example, the discharge rate should be as fast as the cell chemistry can support without overheating the discharging cells 108b, 108c and/or the heat sink 442 of the discharge pathway 442. Such discharge rates may between 60 C and C/5 would be typical. The discharge rate may also be modulated to ensure the fastest possible decline from the high states of charge where the system is most reactive. In some aspects, the discharge system 428 may be configured to discharge the cells 108b one hop away from the failing cell 108a at a rate of up to 20% of the cell 108b's SOC in about 20 seconds, which is a rate of 1% SOC per second. In some aspects, the discharge system 428 may be configured to discharge the cells 108b one hop away from the failing cell 108a at a first discharge rate and/or the cells 108c two hops away from the failing cell 108a at a second discharge rate slower than the first discharge rate. In some aspects, the discharge system 428 may be configured to discharge the cells 108b one hop away from the failing cell 108a at a rate of up to 1% of the cell 108b's SOC in about 1 second. In some aspects, the discharge system 428 may be configured to discharge the cells 108c two hops away from the failing cell 108a at a rate of up to 0.3% of the cell 108c's SOC in about 1 second.

In some aspects, the controller 404 may be configured to monitor the temperature of the discharging cells 108b, 108c. In some aspects, the controller 404 may be configured to stop discharging particular cell(s) 108b, 108c in response to determining that a temperature of the particular cell(s) 108b, 108c exceeds a predefined temperature threshold. In such aspects, the controller 404 may include a hysteresis function to continue discharging the particular cell(s) 108b, 108c in response to determining that the temperature of the particular cell(s) has fallen below the predefined temperature threshold. In some aspects, the predefined temperature threshold is about 30° C.

The discharge system 428 may be selectively coupled with one or more particular cells 108b, 108c proximate a failing cell 108a to discharge the particular cells 108b, 108c. In some aspects, the discharge system 428 may also be coupled with the failing cell 108a. The path of discharge 432 may be configured to direct the thermal energy of the discharging cells 108b, 108c to reduce or minimize effects of the discharging on the cells 108 besides the failing cell 108a and/or the discharging cells 108b, 108c, for example by directing the thermal energy released by the discharging cells 108b, 108c away from the cells 108. For example, the path of discharge 432 may be configured to dissipate the thermal energy to a heat sink separate from the battery pack 104, dissipate the thermal energy evenly to a housing of the battery pack 104, and/or dissipate the energy to a portion of the battery pack 104 that is insensitive or less sensitive to heat to reduce the risk of the thermal energy released by the discharging cells 108a, 108b from causing any cells 108 to undergo thermal runaway. In some aspects, the BMS 400 may be powered by at least a portion of the cells 108 of the battery 104. In some aspects, the BMS 400 may be powered by a different power supply other than the battery 104.

The controller 404 is configured to receive, from the sensor(s) 426, information indicative of a status of each of the cells 108, for example a health status of each of the cells 108. For example, in aspects in which the sensors 426 include voltage sensors, the controller 404 may receive information indicative of the voltage of the cells 108. In aspects in which the sensors 426 include temperature sensors, the controller 404 may receive information indicative of a temperature of the cells 108.

The controller 404 is configured to determine, based on the information received from the sensors 426, a failure status of each of the cells 108. For example, in aspects in which the sensors 426 include voltage sensors, the controller 404 may determine that a particular cell 108 is in a failure condition in response to determining that the cell 108 has experienced a sudden loss in voltage. For example, the controller 404 may determine that a difference between a current voltage of the cell 108 and a previously determined voltage of the cell 108 is above a predefined threshold. In some aspects, the controller 404 may determine the voltage of each of the cells 108 about every second. In some aspects, the controller 404 may determine the SOC of each of the cells 108 for each determined voltage. The controller 404 may then determine that the cell has experienced a sudden loss of voltage in response to determining that a difference between a current SOC of the cell 108 and a previously determined SOC of the cell 108 is above a predefined threshold. In some aspects, the predefined threshold may be C rate of C/10 or greater, which is a divergence rate greater than about 1% per minute.

In other aspects, the controller 404 may compare the sensed voltage of the cell 108 to a predefined voltage threshold, and determine that the cell 108 is in a failure condition in response to determining that the sensed voltage of the cell 108 is below the predefined voltage threshold. In such aspects, the predefined voltage threshold may be about 0.5V or more below the string average voltage for configurations in which the cells 108 are connected in series. In another aspect in which the sensors 426 include voltage sensors, the controller 404 may determine the temperature of the cell 108 based on a pulse modulated width (PWM) voltage signal. The controller 404 may then compare the determined temperature of the cell 108 to a predefined temperature threshold, and determine that the cell 108 is in a failure condition in response to determining that the determined temperature of the cell 108 is above the predefined temperature threshold. The predefined temperature threshold may be based on the chemistry of the cells 108. For example, the predefined temperature threshold for aqueous cells may be lower than the predefined temperature threshold for solid cells. In some aspects, the temperature threshold may be about 85° C. to about 130° C. In some aspects, the temperature threshold may be about 85° C., 90° C., 120° C., or 130° C.

In aspects in which the sensors 426 include temperature sensors, the controller 404 may compare the sensed temperature of the cell 108 to a predefined temperature threshold, and determine that the cell 108 is in a failure condition in response to determining that the sensed temperature of the cell 108 is above the predefined temperature threshold. The predefined temperature threshold may be based on the chemistry of the cells 108. For example, the predefined temperature threshold for aqueous cells may be lower than the predefined temperature threshold for solid cells. In some aspects, the temperature threshold may be about 85° C. to about 130° C. In some aspects, the temperature threshold may be about 85° C., 90° C., 120° C., or 130° C. In some aspects, the controller 404 may compare a sensed or determined temperature of a particular cell 108 to cells one hop or two hops away from the particular cell. In response to determining that a difference in temperature between a particular cell and cells one hop or two hops away is greater than a predefined threshold, the controller may determine that the particular cell is in the failure condition. In some aspects, the predefined threshold may be about 20° C. As used herein, the phrase “failure condition” can refer to (a) a particular cell or cells 108a that are likely to enter thermal runaway, (b) a particular cell or cells 108a that are undergoing thermal runaway, or (c) both cell(s) 108a that are undergoing thermal runaway and cell(s) 108a that are likely to enter thermal runaway. The phrase “cell in the failure condition” is interchangeably referred to as a “failing cell”. As used herein, the phrase “thermal runaway” refers to cells that releasing thermal energy, for example, rapidly releasing a large amount of energy for a particular battery type, which can cause neighboring cells to fail and result in a chain reaction that can cause all of the cells in the battery to fail. Cells that are likely to undergo thermal runaway are not yet in thermal runaway, but are trending toward thermal runaway. For example, the determined voltage and/or temperature of such cells is not yet at the predefined voltage and/or temperature thresholds that indicate thermal runaway, but successively determined voltage and/or temperatures of such cells are increasingly closer to the predefined voltage and/or temperature thresholds that indicate thermal runaway. As used herein, the phrase “cell” or “normal cell” refer to one or more cells 108 that are operating according to specified operating parameters for the cell type.

In some aspects, cells likely to enter thermal runaway may have an internal short circuit, resulting in an internal discharging rate as low as about C/10. In some aspects, cells likely to enter thermal runaway, but that have not yet entered thermal runaway, may have an internal discharging rate of about 3 C or lower. In some aspects, cells likely to enter thermal runaway may have an internal discharging rate from about C/10 to about 3 C. FIGS. 1-3 illustrate three different configurations in which a cell 108a in a failure condition has been identified. Cells 108 that are operating with temperatures and/or voltages at or below the predefined temperature and/or voltage thresholds are determined to be in acceptable operating conditions.

In response to determining that the particular cell 108a is in the failure condition, the controller 404 is configured to access the battery map 420 and retrieve information about the identities about the cells 108b that are one hop away from the failing cell 108a. In some aspects, the controller 404 may access the battery map 420 and retrieve information about the identities of the cells 108c that are two hops away from the failing cell 108a. For example, the controller 404 may retrieve the information about the identities about the cells 108c in response to determining that one or more of the cells 108b is likely to enter the failure condition or is in the failure condition. In some aspects, the controller 404 is configured to determine whether the discharge system 428 can discharge the cells 108b to a target SOC quickly enough to prevent or assist in reducing propagation of the failure condition to the cells 108b. This may occur in configurations in which the discharge circuit 436 is a high-powered discharge circuit. A high-power discharge circuit is configured to discharge a particular cell at a C-rate of 10 C or greater. In response to determining that the discharge system 428 likely cannot discharge the cells 108b to the target SOC fast enough to prevent or assist in reducing propagation of the failure condition to the cells 108b, the discharge system 428 may discharge the cells 108c. This may occur in configurations in which the discharge circuit 436 is a low-powered discharge circuit. A low-powered discharge circuit is configured to discharge a particular cell at a C-rate of C/5 or less.

The controller 404 is then configured to couple the cells 108b with the discharge system 428 such that the cells 108b can be discharged by the discharge system 428. In some aspects, the controller 404 does not couple the cell 108a in the failure condition to the discharge system 428. In other aspects, the controller 404 may couple cell 108a in the failure condition to the discharge system 428 at the same time as the cells 108b are coupled with the discharge system 428 if the controller 404 has determined that the cell 108a is likely to fail but has not yet failed. That is, the cell 108a that is likely to fail is not coupled with the discharge system 428 and/or is not discharged before the cells 108b one hop away from the failing cell 108a are discharged. In other aspects, the controller 404 is configured to couple the cells 108c two hops away from the cell likely to fail 108a with the discharge system 428 such that the cells 108c can be discharged by the discharge system 428 as described above with regard to the cells 108b. Discharged and/or partially discharged cells 108 are less likely to enter the failure condition, release less energy (relative to a cell 108 with a SOC) if the discharged and/or partially discharged cells do fail, and release energy at a lower rate if the discharged and/or partially discharged cells do fail. Therefore, discharging the cells 108b and/or the cells 108c provides a protective “fence” around the failing cell 108a that can prevent or assist in reducing the failure condition from spreading to cells 108 that are not in close proximity to the failing cell 108a. In aspects in which the discharge circuit 436 is a high-power discharge circuit, the BMS 400 may prioritize discharging the cells 108b. In aspects in which the discharge circuit is a low-power circuit, the BMS may prioritize discharging the cells 108c. In some aspects, the discharge circuit 436 may be sufficiently high-powered to discharge both the cells 108b and 108c. In such aspects, the controller 436 may couple both the cells 108b and 108c to the discharge system 428.

The controller 404 may be configured to stop discharging the cells 108b, 108c in response to the SOC of the cells 108b, 108c reaching a target SOC. In some aspects, the cells 108b and/or cells 108c the target SOC is from greater than or equal to 0% SOC to greater than or equal to 70% SOC, greater than or equal to 0% SOC to 40% SOC, preferably from greater than or equal to 10% SOC to less than or equal to 30% SOC, or greater than or equal to 10% SOC to less than or equal to 25% SOC. In some aspects, the target SOC is a reduction in the initial SOC of the cells 108b or 108c to a SOC level equal to or less than 50% of the initial SOC, preferably equal to or less than 30%, and further preferably equal to or less than 20%. This reduces the risk of the cells 108b and/or 108c also going into a failure condition, thereby protecting the remaining cells 108 in the battery 104 and/or equipment including the battery 104. In aspects in which any of the particular cells 108b, 108c are used to power the BMS 400, the SOC of the particular cells 108b, 108c used to power the BMS 400 remains above 0% after discharging.

In some aspects, the controller 404 is configured to control a rate of discharge of the discharge system 428 based on a temperature and/or a voltage of the cells 108b being discharged to prevent or assist in reducing an excessive rise in the temperature of the cells 108b from increasing during discharging. For example, the controller 404 may be configured to control the rate of discharge such that a temperature of the cells 108 adjacent the cells 108b being discharged does not exceed a predefined temperature threshold. In some aspects, the predefined temperature threshold may be about 30° C. In aspects in which the voltage of the cells 108b being discharged is monitored, the controller 404 may determine the temperature of the cells 108b based on the voltage of the cells 108b. For example, in some aspects, the controller 404 is configured to control the rate of discharging such that the temperature of the cells 108b being discharged is below a first temperature threshold. In some aspects, the first temperature threshold is 100° C. In such aspects, the controller 404 is configured to slow or stop the rate of discharging in response to the temperature of the cells 108b reaching the first temperature threshold. In some aspects, the controller 404 is configured to control the rate of discharging such that the temperature of the cells 108b being discharged is within a second temperature threshold greater than the first temperature threshold. In some aspects, the second temperature threshold is 100° C. to 130° C. The controller 404 is configured to use the second temperature threshold based on cell chemistry and design. For example, aqueous battery systems may have lower temperature thresholds than solid battery systems. In such aspects, the controller 404 is configured to slow or stop the rate of discharging in response to the temperature of the cells 108b reaching the second temperature threshold. The controller 404 is configured to prevent or assist in reducing the temperature of the cells 108b from exceeding a third temperature threshold greater than the second temperature threshold during discharging. In some aspects, the third temperature threshold is 130° C. In such aspects, the controller 404 is configured to slow or stop the rate of discharging in response to the temperature of the cells 108b reaching the third temperature threshold. In aspects in which the cells 108c are discharged, the controller 404 is configured to control the rate of discharge of the cells 108c as described above with regard to the cells 108b.

In some aspects, the controller 404 is configured to control the rate of discharging of the cells 108b based on the battery C-rating. The C-rating is a measure of the rate a battery is charged or discharged relative to its maximum capacity. A 1 C rate means a current which will discharge the entire capacity of the battery 104 in one hour. Thus, for example, for a battery with a capacity of 100 ampere-hrs, a C rate discharge would be a discharge current of 100 amperes, a 5 C rate for this battery would be 500 amperes, and a C/2 rate would be 50 amperes. In such aspects, the controller 404 is configured to discharge the cells 108b at a rate of greater than or equal to C/60 and less than or equal to 5 C, and preferably greater than or equal to C/20 and less than or equal to C/5. In aspects in which the cells 108c are discharged, the controller 404 is configured to control the rate of discharge of the cells 108c as described above with regard to the cells 108b.

In some aspects, the rate of discharge of the cells 108b can be increased as necessary to reduce or prevent the failure condition in the failing cell 108a from inducing failure of the cells 108b.

In some aspects, the controller 404 is configured to discharge the cells 108 to the target SOC before the battery 104 is shipped, thereby reducing the risk of a thermal runaway event occurring during shipping.

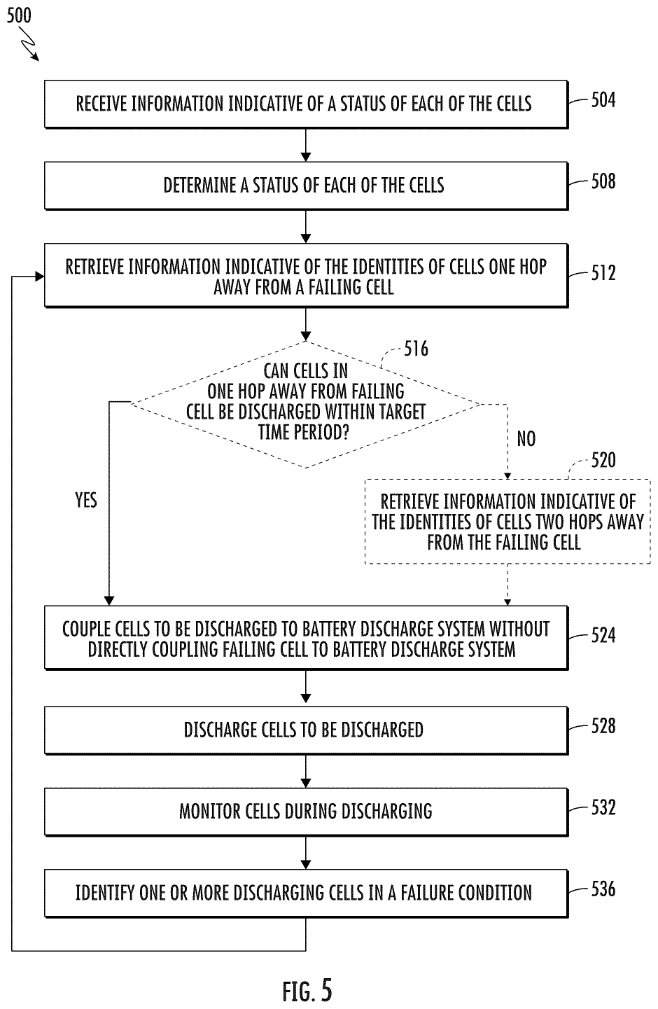

FIG. 5 illustrates a method 500 for reducing the risk of propagation of thermal runaway in a rechargeable battery 104, such as the battery 104. The method 500 may be conducted by the controller 404 of the BMS 400. The method 500 may be used for conditions in which the failure condition includes cell(s) 108a that are undergoing thermal runaway and/or cell(s) 108a that are likely to undergo thermal runaway.

At 504, information indicative of a status of each of the cells is received. For example, the controller 404 receives, from the sensor(s) 426, information indicative of a status of each of the cells 108. In aspects in which the sensors 426 include voltage sensors, the controller 404 may receive information indicative of the voltage of the cells 108. In aspects in which the sensors 426 include temperature sensors, the controller 404 may receive temperature information indicative of a temperature of the cells 108. In aspects in which the sensors 426 include both temperature sensors and voltage sensors, the controller 404 may receive information indicative of the voltage and the temperature of the cells 108.

At 508, a status of each of the cells 108 is determined. For example, the controller 404 determines, based on the information received from the sensors 426, a status of each of the cells 108. The status may indicate that the cell 108 is in acceptable operating conditions or that the cell 108 is in the failure condition.

At 512, information indicative of the identities of the cells 108b one hop away from the failing cell 108a is retrieved. For example, in response to determining that one or more cell(s) 108a is in a failure condition, the controller 404 accesses the battery map 420 and retrieves information about the identities about the cells 108b one hop away from the failing cell 108a. In aspects in which both the cells 108b and 108c can be discharged, the controller 404 may access the battery map 420 and retrieves information about the identities about the cells 108b one hop away and the cells 108c two hops away from the failing cell 108a.

At 516, which is optional, it is determined whether the cells 108b one hop away from the failing cell 108a can be discharged within a target time period. For example, the controller 404 may determine whether the battery discharge system 428 can discharge the cells 108b to a target SOC within a target time period and/or at a target discharge rate. As used herein, the target time period is a period of time that it takes for the cells 108b to be discharged to a SOC reduces the risk that failure of the cells 108b will also cause failure of the cells 108c. In some aspects, the target rate may be between 60 C and C/5. In some aspects, the target rate may be between 10 C and C/10. In some aspects, the target discharge rate may be at a rate of up to 20% of the cell 108b's SOC in about 20 seconds, which is a rate of 1% SOC per second (e.g., a C-rate of C/2).

At 520, which is optional, information indicative of the identities of the cells 108c two hops away from the failing cell 108a is retrieved. For example, in response to determining that the battery discharge system 428 cannot discharge the cells 108b to the target SOC within the target time period, the controller 404 accesses the battery map 420 and retrieve information about the identities about the cells 108c in close proximity to the cell 108b.

At 524, the cells 108b, 108c to be discharged are coupled to the battery discharge system 428 without directly coupling the failing cell 108a to the battery discharge system. For example, the controller 404 couples the cells to be discharged (e.g., the cells 108b or 108c) with the battery discharge system 428 such that the cells 108b or 108c can be discharged by the battery discharge system 428. The controller 404 does not couple the cell 108a in the failure condition to the discharge system 428. For example, the controller 404 may not directly couple the cell 108a in the failure condition to the discharge system 428. In aspects that include 520, the controller 404 instead couples the cells 108c with the battery discharge system 428 such that the cells 108c can be discharged by the battery discharge system 428. In aspects in which the cells 108b, 108c are both discharged, the controller 404 couples the cells 108b and the cells 108c with the battery discharge system 428.

At 528, the cells 108b and/or 108c are discharged by the battery discharge system 428. In some aspects, the cells 108b and/or 108c are discharged to a SOC from greater than or equal to 0% SOC to 40% SOC, preferably from greater than or equal to 10% SOC to less than or equal to 30% SOC, or greater than or equal to 10% SOC to less than or equal to 25% SOC. In some aspects, the target SOC is a reduction in the initial SOC of the cells 108b or 108c to a SOC level equal to or less than 50% of the initial SOC, preferably equal to or less than 30%, and further preferably equal to or less than 20%. This reduces the risk of the cells 108b and/or 108c also going into a failure condition, thereby protecting the remaining cells 108 in the battery 104 and/or equipment including the battery 104. In some aspects, the controller 404 is configured to control a rate of discharge of the cells 108b, 108c based on a temperature of the cells 108b, 108c being discharged, to prevent or assist in reducing an excessive rise in the temperature of the cells 108b, 108c from increasing during discharging. In some aspects, the controller 404 is configured to control the rate of discharging of the cells 108b, 108c based on the battery C-rating.

At 532, the controller 404 monitors the cells 108b or 108c during discharging.

At 536, one or more discharging cells 108b, 108c are identified as being in the failure condition. For example, in response to determining that any of the cells 108b or 108c has failed or is likely to fail during discharging, the controller 404 returns to 512.

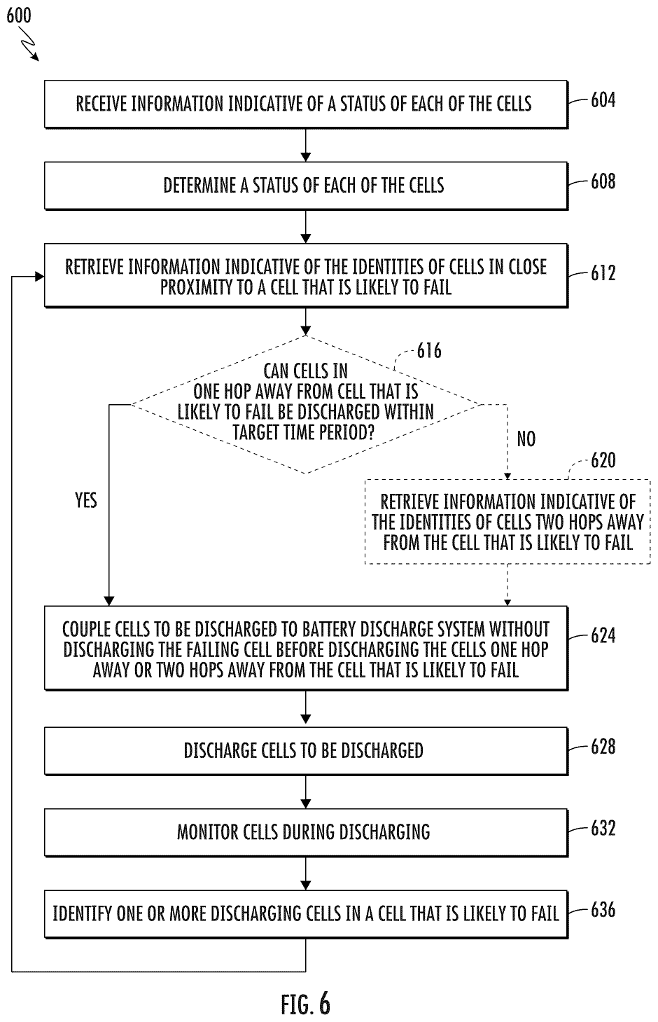

FIG. 6 illustrates a method 600 for reducing the risk of propagation of thermal runaway in a rechargeable battery 104, such as the battery 104. The method 600 may be conducted by the controller 404 of the BMS 400. The method 600 may be substantially similar to the method 500 except as described in greater detail below. The method 500 may be used for conditions in which the failure condition includes cell(s) 108a that are likely to undergo thermal runaway (e.g., cell(s) 108a that are likely to fail).

At 624, the cells to be discharged 108a, 108b, 108c are coupled to the battery discharge system without discharging the cell that is likely to fail 108a before the cells 108b one hop or the cells 108c two hops from the cell 108a that is likely to fail are discharged. For example, the controller 404 couples the cells 108b and the cell that is likely to fail 108a with the battery discharge system 428 such that the cells 108b and 108a can be discharged by the battery discharge system. The cell 108a that is likely to fail is coupled with the discharge system 428 at substantially the same time as the cells 108b are coupled with the discharge system 428 such that the cell 108a that is likely fail is not discharged before the cells 108b are discharged.

For purposes of completeness, the method 600 is described in detail below.

At 604, information indicative of a status of each of the cells is received. For example, the controller 404 receives, from the sensor(s) 426, information indicative of a status of each of the cells 108. In aspects in which the sensors 426 include voltage sensors, the controller 404 may receive information indicative of the voltage of the cells 108. In aspects in which the sensors 426 include temperature sensors, the controller 404 may receive temperature information indicative of a temperature of the cells 108. In aspects in which the sensors 426 include both temperature sensors and voltage sensors, the controller 404 may receive information indicative of the voltage and the temperature of the cells 108.

At 608, a status of each of the cells 108 is determined. For example, the controller 404 determines, based on the information received from the sensors 426, a status of each of the cells 108. The status may indicate that the cell 108 is in acceptable operating conditions or that the cell 108 is in the failure condition and is likely to fail, but has not yet failed. For example, the cell 108a in the failure condition may have a short circuit discharging at a rate of up to about C/10.

At 612, information indicative of the identities of the cells 108b one hop away from the failing cell 108a is retrieved. For example, in response to determining that one or more cell(s) 108a is in a failure condition, the controller 404 accesses the battery map 420 and retrieves information about the identities about the cells 108b one hop away from the failing cell 108a. In aspects in which both the cells 108b and 108c can be discharged, the controller 404 may access the battery map 420 and retrieves information about the identities about the cells 108b one hop away and the cells 108c two hops away from the cell 108a that is likely to fail.

At 616, which is optional, it is determined whether the cells 108b one hop away from the failing cell 108a can be discharged within a target time period. For example, the controller 404 may determine whether the battery discharge system 428 can discharge the cells 108b to a target SOC within a target time period and/or a target discharge rate. As used herein, the target time period is a period of time that it takes for the cells 108b to be discharged to a SOC reduces the risk that failure of the cells 108b will also cause failure of the cells 108c. In some aspects, the target discharge rate may be between 60C and C/5. In some aspects, the target discharge rate may be between 10C and C/10. In some aspects, the target discharge rate may be at a rate of up to 20% of the cell 108b's SOC in about 20 seconds, which is a rate of 1% SOC per second (e.g., a C-rate of C/2).

At 620, which is optional, information indicative of the identities of the cells 108c two hops away from the cell 108a that is likely to fail is retrieved. For example, in response to determining that the battery discharge system 428 cannot discharge the cells 108b to the target SOC within the target time period, the controller 404 accesses the battery map 420 and retrieve information about the identities about the cells 108c in close proximity to the cell 108b.

At 624, the cells to be discharged 108a, 108b, 108c are coupled to the battery discharge system without discharging the cell 108a that is likely to fail before the cells 108b one hop or the cells 108c two hops from the cell 108a that is likely to fail are discharged. For example, the controller 404 couples the cells 108b and the failing cell 108a with the battery discharge system 428 such that the cells 108b and 108a can be discharged by the battery discharge system. The cell 108a that is likely to fail is coupled with the discharge system 428 at substantially the same time as the cells 108b are coupled with the discharge system 428 such that the failing cell 108a not discharged before the cells 108b are discharged. In aspects in which the cells 108b, 108c are both discharged, the controller 404 couples the cells 108b and the cells 108c with the battery discharge system 428.

At 628, the cells 108b or 108c are discharged by the battery discharge system 428. In some aspects, the cells 108b and/or 108c are discharged to a SOC from greater than or equal to 0% SOC to 40% SOC, preferably from greater than or equal to 10% SOC to less than or equal to 30% SOC, or greater than or equal to 10% SOC to less than or equal to 25% SOC. In some aspects, the target SOC is a reduction in the initial SOC of the cells 108b or 108c to a SOC level equal to or less than 50% of the initial SOC, preferably equal to or less than 30%, and further preferably equal to or less than 20%. This reduces the risk of the cells 108b and/or 108c also going into a failure condition, thereby protecting the remaining cells 108 in the battery 104 and/or equipment including the battery 104. In some aspects, the controller 404 is configured to control a rate of discharge of the cells 108b, 108c based on a temperature of the cells 108b, 108c being discharged, to prevent or assist in reducing an excessive rise in the temperature of the cells 108b, 108c from increasing during discharging. In some aspects, the controller 404 is configured to control the rate of discharging of the cells 108b, 108c based on the battery C-rating.

At 632, the controller 404 monitors the cells 108b or 108c during discharging.

At 636, one or more discharging cells 108b, 108c are identified as being in the failure condition. For example, in response to determining that any of the cells 108b or 108c is likely to fail during discharging, the controller 404 returns to 612.

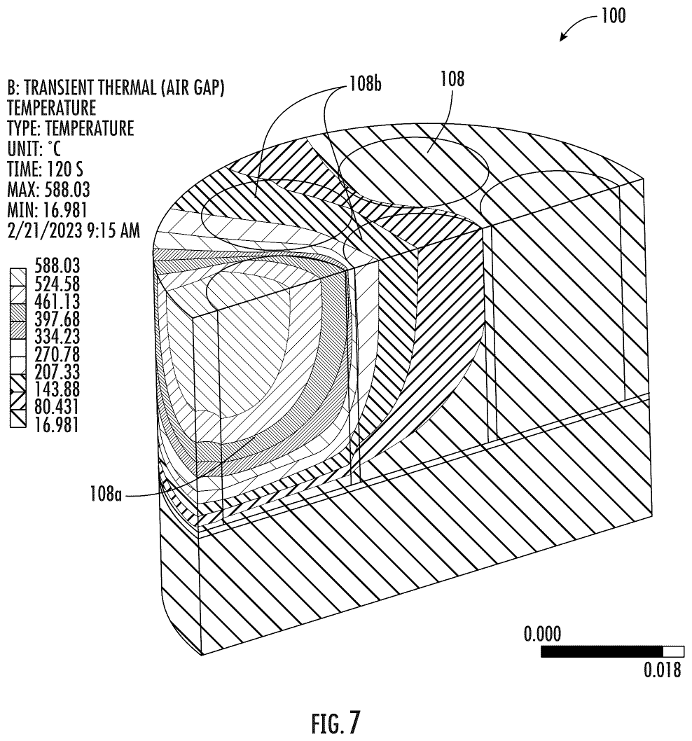

FIG. 7 illustrates a temperature map (e.g., a heat map) of the battery 104 in which the cell 108a is undergoing a thermal runaway event and the cells 108b have been discharged. As shown in FIG. 7, discharging the cells 108b forms a protective fence that prevents or assists in reducing the high temperatures produced by the failing cells 108a from reaching the other cells 108 in the battery 104. Therefore, discharging the cells in close contact with the failing cell provides a protective “fence” around the failing cell that can prevent or assist in reducing the failure condition from spreading to cells that are not in close proximity to the failing cell. This can protect the remaining cells in the battery and/or prevent or assist in reducing damage of device(s) coupled with the battery.

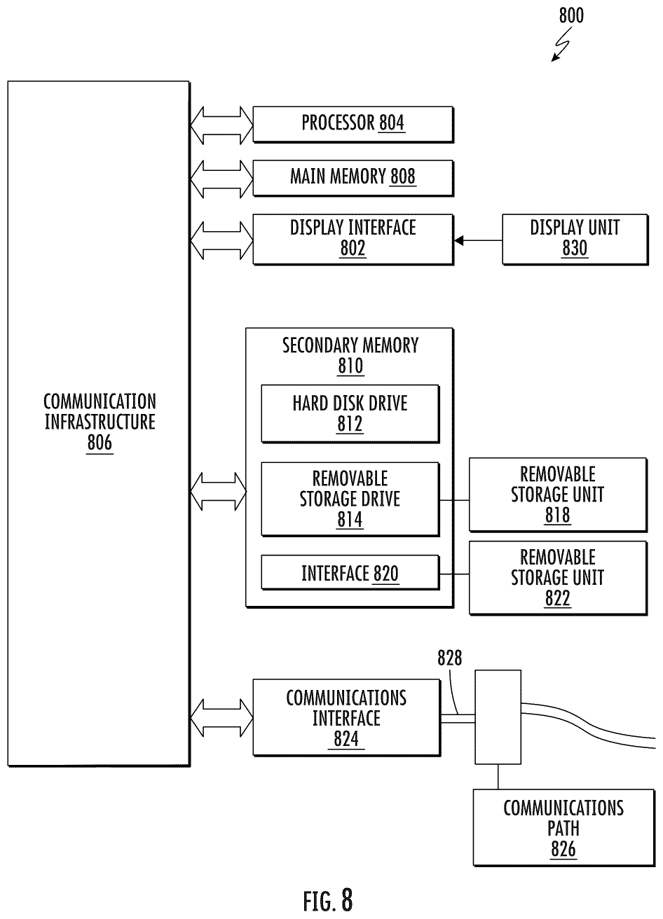

FIG. 8 presents an example system diagram of various hardware components and other features, for use in accordance with an aspect of the present disclosure. Aspects of the present disclosure may be implemented using hardware, software, or a combination thereof and may be implemented in one or more computer systems or other processing systems. In one example variation, aspects described herein may be directed toward one or more computer systems capable of carrying out the functionality described herein of the BMS 400. An example of such a computer system 800 is shown in FIG. 8.

The computer system 800 includes one or more processors, such as processor 1004. The processor 804 is connected to a communication infrastructure 806 (e.g., a communications bus, cross-over bar, or network). The processor 804 may include a processor for the local computing system 404 of FIG. 4A. Various software embodiments are described in terms of this example computer system. After reading this description, it will become apparent to a person skilled in the relevant art(s) how to implement embodiments described herein using other computer systems and/or architectures.

Computer system 800 may include a display interface 802 that forwards graphics, text, and other data from the communication infrastructure 806 (or from a frame buffer not shown) for display on a display unit 830. Computer system 800 also includes a main memory 808, preferably random access memory (RAM), and may also include a secondary memory 810. The secondary memory 810 may include, for example, a hard disk drive 812 and/or a removable storage drive 814, representing a floppy disk drive, a magnetic tape drive, an optical disk drive, etc. The removable storage drive 814 reads from and/or writes to a removable storage unit 818 in a well-known manner. Removable storage unit 818, represents a floppy disk, magnetic tape, optical disk, etc., which is read by and written to removable storage drive 814. As will be appreciated, the removable storage unit 818 includes a computer usable storage medium having stored therein computer software and/or data.

In alternative embodiments, secondary memory 810 may include other similar devices for allowing computer programs or other instructions to be loaded into computer system 800. Such devices may include, for example, a removable storage unit 822 and an interface 820. Examples of such may include a program cartridge and cartridge interface (such as that found in video game devices), a removable memory chip (such as an erasable programmable read only memory (EPROM), or programmable read only memory (PROM)) and associated socket, and other removable storage units 822 and interfaces 820, which allow software and data to be transferred from the removable storage unit 822 to computer system 800. In an example, memory for the computing system 400 may include the main memory 808, the secondary memory 810, the removable storage drive 814, the removable storage unit 818, the removable storage unit 822, etc.

The computer system 800 may also include a communications interface 824. Communications interface 824 allows software and data to be transferred between computer system 800 and external devices. Examples of communications interface 824 may include a modem, a network interface (such as an Ethernet card), a communications port, a Personal Computer Memory Card International Association (PCMCIA) slot and card, etc. Software and data transferred via communications interface 824 are in the form of signals 828, which may be electronic, electromagnetic, optical or other signals capable of being received by communications interface 824. These signals 828 are provided to communications interface 824 via a communications path (e.g., channel) 826. This path 826 carries signals 828 and may be implemented using wire or cable, fiber optics, a telephone line, a cellular link, a radio frequency (RF) link and/or other communications channels. In this document, the terms “computer program medium” and “computer usable medium” are used to refer generally to media such as a removable storage drive, a hard disk installed in a hard disk drive, and/or signals 828. These computer program products provide software to the computer system 800. Embodiments described herein may be directed to such computer program products.

Computer programs (also referred to as computer control logic) are stored in main memory 808 and/or secondary memory 810. Computer programs may also be received via communications interface 824. Such computer programs, when executed, enable the computer system 800 to perform various features in accordance with embodiments described herein. In particular, the computer programs, when executed, enable the processor 804 to perform such features. Accordingly, such computer programs represent controllers of the computer system 800.

In variations where embodiments described herein are implemented using software, the software may be stored in a computer program product and loaded into computer system 800 using removable storage drive 814, hard disk drive 812, or communications interface 820. The control logic (software), when executed by the processor 804, causes the processor 804 to perform the functions in accordance with embodiments described herein as described herein. In another variation, embodiments are implemented primarily in hardware using, for example, hardware components, such as application specific integrated circuits (ASICs). Implementation of the hardware state machine so as to perform the functions described herein will be apparent to persons skilled in the relevant art(s).

In yet another example variation, embodiments described herein are implemented using a combination of both hardware and software.

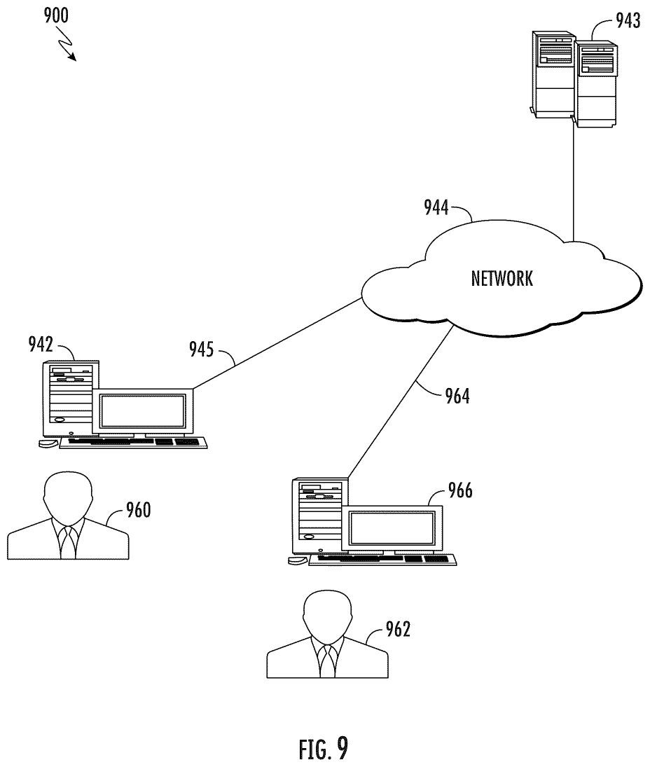

FIG. 9 is a block diagram of various example system components for use in accordance with embodiments of the present disclosure. FIG. 9 shows a communication system 900 usable in accordance with embodiments described herein. The communication system 900 may include one or more users 960, 962 and one or more terminals 942, 966. For example, terminals 942, 966 may include the control system 920 or a related system, and/or the like. In one embodiment, data for use in accordance with embodiments described herein is, for example, input and/or accessed by users 960, 962 via terminals 942, 966, such as personal computers (PCs), minicomputers, mainframe computers, microcomputers, telephonic devices, or wireless devices, such as personal digital assistants (“PDAs”) or a hand-held wireless devices coupled with a server 943, such as a PC, minicomputer, mainframe computer, microcomputer, or other device having a processor and a repository for data and/or connection to a repository for data, via, for example, a network 944, such as the Internet or an intranet, and couplings 945, 946, 964. The couplings 945, 946, 964 include, for example, wired, wireless, or fiberoptic links. In another example variation, the method and system in accordance with embodiments described herein operate in a stand-alone environment, such as on a single terminal.

Set forth below are various aspects of the disclosure.

Thus, one of more aspects of the present disclosure may be implemented according to one or more of the following clauses.

Clause 1. A system for reducing battery cell failure propagation risk of a rechargeable battery, the system comprising: a rechargeable battery including a plurality of rechargeable cells connected in series, parallel, or a combination of series and parallel; and a battery management system (BMS) coupled with the battery, the BMS comprising a processor and a memory, the processor configured to execute computer-executable instructions stored on the memory, the memory including computer-executable instructions to: receive, from one or more sensors, information indicative of a status of each of the rechargeable cells of the plurality of rechargeable cells; determine, based on the information indicative of the status of the plurality of rechargeable cells, that a particular rechargeable cell is likely in a failure condition, wherein the failure condition includes at least one of undergoing thermal runaway and likely to enter thermal runway; identify a group of rechargeable cells of the plurality rechargeable cells that is in within one hop of the rechargeable cell that is likely in the failure condition; couple the group of rechargeable cells to a discharging system without coupling the rechargeable cell in the failure condition to the discharging system; and discharge the group of rechargeable cells to a target State of Charge (SOC).

Clause 2. The system of clause 1, wherein the information indicative of the status of one of each of the rechargeable cells is information indicative of a temperature, a voltage, or both a temperature and a voltage of each of the rechargeable cells.

Clause 3. The system of any one of clauses 1-2, wherein the computer-executable instructions include determining a rate of discharge of the group based on the information indicative of the status of the group of rechargeable cells to reduce a cell failure propagation risk.

Clause 4. The system of any one of clauses 1-3, wherein the group of rechargeable cells is discharged to a SOC of 0% to 70%.

Clause 5. The system of any one of clauses 1-4, wherein the information indicative of the status of the plurality of rechargeable cells is a temperature, and determining that a cell is likely in the failure condition includes determining that the temperature of a particular rechargeable cell is above a temperature threshold.

Clause 6. The system of any one of clauses 1-5, wherein the information indicative of the temperature is determined based on information indicative of a voltage of each of the rechargeable cells.

Clause 7. A system for reducing battery cell failure propagation risk of a rechargeable battery, the system comprising: a rechargeable battery including a plurality of rechargeable cells connected in series, parallel, or a combination of series and parallel; and a battery management system (BMS) coupled with the battery, the BMS comprising a processor and a memory, the processor configured to execute computer-executable instructions stored on the memory, the memory including computer-executable instructions to: receive, from one or more sensors, information indicative of a status of each of the rechargeable cells of the plurality of rechargeable cells; determine, based on the information indicative of the status of the plurality of rechargeable cells, that a particular rechargeable cell is likely in a failure condition, wherein the failure condition includes cells likely to undergo thermal runaway; identify a group of rechargeable cells of the plurality rechargeable cells that is one hop away from the rechargeable cell that is likely in the failure condition; couple the group of rechargeable cells and the cell that is likely in the failure condition to a discharging system; and discharge the group of rechargeable cells and the cell in the failure condition to a target State of Charge (SOC), wherein the cell that is likely in the failure condition is not discharged before the group of rechargeable cells is discharged.

Clause 8. The system of clause 7, wherein the information indicative of the status of one of each of the rechargeable cells is information indicative of a temperature, a voltage, or both a temperature and a voltage of each of the rechargeable cells.

Clause 9. The system any one of clauses 7-8, wherein the computer-executable instructions include determining a rate of discharge of the group based on the information indicative of the status of the group of rechargeable cells to reduce a cell failure propagation risk.

Clause 10. The system of any one of clauses 7-9, wherein the group of rechargeable cells is discharged to a SOC of 0% to 70%.

Clause 11. The system of any one of clauses 7-10, wherein the information indicative of the status of the plurality of rechargeable cells is a temperature, and determining that a cell is likely in the failure condition includes determining that the temperature of a particular rechargeable cell is above a temperature threshold.

Clause 12. The system of any one of clauses 7-11, wherein the cell that is likely in the failure condition has an internal short circuit having an internal discharging rate from about C/10 to about 3 C.

Clause 13. A system for reducing battery cell failure propagation risk of a rechargeable battery, the system comprising: a rechargeable battery including a plurality of rechargeable cells connected in series, parallel, or a combination of series and parallel; and a battery management system (BMS) coupled with the battery, the BMS comprising a processor and a memory, the processor configured to execute computer-executable instructions stored on the memory, the memory including computer-executable instructions to: receive, from one or more sensors, information indicative of a status of each of the rechargeable cells of the plurality of rechargeable cells; determine, based on the information indicative of the status of the plurality of rechargeable cells, that a particular rechargeable cell is likely in a failure condition; identify a first group of rechargeable cells of the plurality rechargeable cells that is one hop away from the rechargeable cell that is likely in the failure condition; identify a second group of rechargeable cells of the plurality rechargeable cells that two hops away from the rechargeable cell that is likely in the failure condition; in response to determining that the first group of cells can likely be discharged before the cells in the first group of rechargeable cells enter the failure condition, couple the first group of rechargeable cells to a discharging system and discharge the first group of rechargeable cells to a target State of Charge (SOC); or in response to determining that the first group of rechargeable cells cannot likely be discharged before the cells in the first group of rechargeable cells enter the failure condition, couple the second group of rechargeable cells to the discharging system and discharge the second group of rechargeable cells to the target SOC.

Clause 14. The system of clause 13, wherein the first group of rechargeable cells or the second group of rechargeable cells is coupled with the discharging system without coupling the rechargeable cell in the failure condition to the discharging system.

Clause 15. The system of clause 13, wherein the cell in the failure condition is coupled with the discharging system and cell in the failure condition and the first group or the second group of rechargeable cells are discharged such that the cell in the failure condition is not discharged before the group of rechargeable cells is discharged.

Clause 16. The system of any one of clauses 13-15, wherein the information indicative of the status of one of each of the rechargeable cells is information indicative of a temperature, a voltage, or both a temperature and a voltage of each of the rechargeable cells.

Clause 17. The system of any one of clauses 13-16, wherein the computer-executable instructions include determining a rate of discharge of the group based on the information indicative of the status of the group of rechargeable cells to reduce a cell failure propagation risk.

Clause 18. The system of any one of clauses 13-16, wherein the group of rechargeable cells is discharged to a SOC of 0% to 70%.

Clause 19. The system of any one of clauses 13-18, wherein the information indicative of the status of the plurality of rechargeable cells is a temperature, and determining that a cell is likely in the failure condition includes determining that the temperature of a particular rechargeable cell is above a temperature threshold.

Clause 20. The system of any one of clauses 13-20, wherein the information indicative of the temperature is determined based on information indicative of a voltage of each of the rechargeable cells.

For the purpose of this disclosure, the term “coupled” means the joining or linking of two members directly or indirectly to one another. Such joining may be stationary or moveable in nature.

It will be appreciated that various implementations of the above-disclosed and other features and functions, or alternatives or varieties thereof, may be desirably combined into many other different systems or applications. Also, that various presently unforeseen or unanticipated alternatives, modifications, variations, or improvements therein may be subsequently made by those skilled in the art which are also intended to be encompassed by the following claims.

What is claimed is:

1. A system for reducing battery cell failure propagation risk of a rechargeable battery, the system comprising:
a rechargeable battery including a plurality of rechargeable cells connected in series, parallel, or a combination of series and parallel; and
a battery management system (BMS) coupled with the battery, the BMS comprising a processor and a memory, the processor configured to execute computer-executable instructions stored on the memory, the memory including computer-executable instructions to:
receive, from one or more sensors, information indicative of a status of each of the rechargeable cells of the plurality of rechargeable cells;
determine, based on the information indicative of the status of the plurality of rechargeable cells, that a particular rechargeable cell is likely in a failure condition, wherein the failure condition includes at least one of undergoing thermal runaway and likely to enter thermal runway;
identify a group of rechargeable cells of the plurality rechargeable cells that is in within one hop of the rechargeable cell that is likely in the failure condition;
couple the group of rechargeable cells to a discharging system without coupling the rechargeable cell in the failure condition to the discharging system; and
discharge the group of rechargeable cells to a target State of Charge (SOC).

2. The system of claim 1, wherein the information indicative of the status of one of each of the rechargeable cells is information indicative of a temperature, a voltage, or both a temperature and a voltage of each of the rechargeable cells.

3. The system of claim 1, wherein the computer-executable instructions include determining a rate of discharge of the group based on the information indicative of the status of the group of rechargeable cells to reduce a cell failure propagation risk.

4. The system of claim 1, wherein the group of rechargeable cells is discharged to a SOC of 0% to 70%.

5. The system of claim 1, wherein the information indicative of the status of the plurality of rechargeable cells is a temperature, and determining that a cell is likely in the failure condition includes determining that the temperature of a particular rechargeable cell is above a temperature threshold.

6. The system of claim 5, wherein the information indicative of the temperature is determined based on information indicative of a voltage of each of the rechargeable cells.

7. A system for reducing battery cell failure propagation risk of a rechargeable battery, the system comprising:
a rechargeable battery including a plurality of rechargeable cells connected in series, parallel, or a combination of series and parallel; and
a battery management system (BMS) coupled with the battery, the BMS comprising a processor and a memory, the processor configured to execute computer-executable instructions stored on the memory, the memory including computer-executable instructions to:
receive, from one or more sensors, information indicative of a status of each of the rechargeable cells of the plurality of rechargeable cells;
determine, based on the information indicative of the status of the plurality of rechargeable cells, that a particular rechargeable cell is likely in a failure condition, wherein the failure condition includes cells likely to undergo thermal runaway;
identify a group of rechargeable cells of the plurality rechargeable cells that is one hop away from the rechargeable cell that is likely in the failure condition;
couple the group of rechargeable cells and the cell that is likely in the failure condition to a discharging system; and
discharge the group of rechargeable cells and the cell in the failure condition to a target State of Charge (SOC), wherein the cell that is likely in the failure condition is not discharged before the group of rechargeable cells is discharged.

8. The system of claim 7, wherein the information indicative of the status of one of each of the rechargeable cells is information indicative of a temperature, a voltage, or both a temperature and a voltage of each of the rechargeable cells.

9. The system of claim 7, wherein the computer-executable instructions include determining a rate of discharge of the group based on the information indicative of the status of the group of rechargeable cells to reduce a cell failure propagation risk.

10. The system of claim 7, wherein the group of rechargeable cells is discharged to a SOC of 0% to 70%.

11. The system of claim 7, wherein the information indicative of the status of the plurality of rechargeable cells is a temperature, and determining that a cell is likely in the failure condition includes determining that the temperature of a particular rechargeable cell is above a temperature threshold.

12. The system of claim 7, wherein the cell that is likely in the failure condition has an internal short circuit having an internal discharging rate from about C/10 to about 3 C.

13. A system for reducing battery cell failure propagation risk of a rechargeable battery, the system comprising:
a rechargeable battery including a plurality of rechargeable cells connected in series, parallel, or a combination of series and parallel; and
a battery management system (BMS) coupled with the battery, the BMS comprising a processor and a memory, the processor configured to execute computer-executable instructions stored on the memory, the memory including computer-executable instructions to:
receive, from one or more sensors, information indicative of a status of each of the rechargeable cells of the plurality of rechargeable cells;
determine, based on the information indicative of the status of the plurality of rechargeable cells, that a particular rechargeable cell is likely in a failure condition;
identify a first group of rechargeable cells of the plurality rechargeable cells that is one hop away from the rechargeable cell that is likely in the failure condition;
identify a second group of rechargeable cells of the plurality rechargeable cells that two hops away from the rechargeable cell that is likely in the failure condition;
in response to determining that the first group of cells can likely be discharged before the cells in the first group of rechargeable cells enter the failure condition, couple the first group of rechargeable cells to a discharging system and discharge the first group of rechargeable cells to a target State of Charge (SOC); or
in response to determining that the first group of rechargeable cells cannot likely be discharged before the cells in the first group of rechargeable cells enter the failure condition, couple the second group of rechargeable cells to the discharging system and discharge the second group of rechargeable cells to the target SOC.

14. The system of claim 13, wherein the first group of rechargeable cells or the second group of rechargeable cells is coupled with the discharging system without coupling the rechargeable cell in the failure condition to the discharging system.

15. The system of claim 13, wherein the cell in the failure condition is coupled with the discharging system and cell in the failure condition and the first group or the second group of rechargeable cells are discharged such that the cell in the failure condition is not discharged before the group of rechargeable cells is discharged.

16. The system of claim 13, wherein the information indicative of the status of one of each of the rechargeable cells is information indicative of a temperature, a voltage, or both a temperature and a voltage of each of the rechargeable cells.

17. The system of claim 13, wherein the computer-executable instructions include determining a rate of discharge of the group based on the information indicative of the status of the group of rechargeable cells to reduce a cell failure propagation risk.

18. The system of claim 13, wherein the group of rechargeable cells is discharged to a SOC of 0% to 70%.

19. The system of claim 13, wherein the information indicative of the status of the plurality of rechargeable cells is a temperature, and determining that a cell is likely in the failure condition includes determining that the temperature of a particular rechargeable cell is above a temperature threshold.

20. The system of claim 19, wherein the information indicative of the temperature is determined based on information indicative of a voltage of each of the rechargeable cells.
